(19) United States
(12) Patent Application Publication
(10) Pub. No.: US 2024/0234205 A9
(43) Pub. Date: Jul. 11, 2024

(54) METHODS FOR FILLING A RECESSED FEATURE ON A SUBSTRATE AND RELATED STRUCTURES

(71) Applicant: ASM IP Holding B.V., Almere (NL)

(72) Inventors: YoungChol Byun, Tempe, AZ (US); Holger Saare, Scottsdale, AZ (US); Salvatore Luiso, Tempe, AZ (US); Jaebeom Lee, Tempe, AZ (US)

(21) Appl. No.: 18/381,232

(22) Filed: Oct. 18, 2023

Related U.S. Application Data
(60) Provisional application No. 63/418,197, filed on Oct. 21, 2022.

(51) Int. Cl. H01L 21/768

(52) U.S. Cl. CPC H01L 21/76877; H01L 21/76843; H01L 21/76865; H01L 21/28568

(57) ABSTRACT

Methods for filling a recessed feature on a substrate are disclosure. The methods may include, providing a substrate with a recessed feature including a metal liner layer, partially etching the metal liner, and subsequently filing the recessed feature with a gap-fill material employing a combination of etch and cyclical deposition processes. Semiconductor structures including a gap fill metal film disposed in a recessed featured are also disclosed.

### CROSS-REFERENCE TO RELATED APPLICATIONS

This application is a nonprovisional of, and claims priority to and the benefit of, U.S. Provisional Patent Application No. 63/418,197, filed Oct. 21, 2022 and entitled “METHODS FOR FILLING A RECESSED FEATURE ON A SUBSTRATE AND RELATED STRUCTURES,” which is hereby incorporated by reference herein.

### FIELD OF INVENTION

The present disclosure relates generally to the field of semiconductor processing methods and systems, and to the field of device and integrated circuit manufacture. In particular, the present the disclosure generally relates to methods for filling a recessed feature on a substrate and structures including a filled recessed feature.

### BACKGROUND OF THE DISCLOSURE

Fabrication processes for forming semiconductor device structures, such as, for example, transistors, memory elements, and integrated circuits, are wide ranging and may include deposition processes, etch processes, thermal annealing processes, lithography processes, and doping processes, amongst others.

A particular fabrication process involves the deposition of a material into a recessed feature on a substrate, thereby filling the recessed feature (or gap) with the material, a process commonly referred to as “gap-fill”. A non-planar substrate may comprise a multitude of recessed features, for example, the recessed features may comprise, vertical recessed features disposed between protruding portions of a substrate surface or indented recessed features formed in a substrate surface.

As semiconductor device structure geometries decrease and high aspect ratio features have become more common place in such device structures as DRAM, flash memory, and logic, it has become increasingly complex to fill the multitude of recessed features with a material having the desired characteristics.

Deposition methods such as high density plasma (HDP), sub-atmospheric chemical vapor deposition (SACVD), and low pressure chemical vapor deposition (LPCVD) have been employed in gap-fill processes, but these and other processes commonly do not achieve the desired gap-fill results.

Accordingly, methods are desired for filling recessed features on a substrate with a material, such as a metal, with improved characteristics.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Methods for filling a recessed feature on a substrate are provided, the methods comprising, providing a substrate including a recessed feature; the recessed feature comprising, sidewalls, a bottom surface, and an opening, and a metal liner layer disposed over at least the sidewalls, and the bottom surface. The methods further include, removing at least a portion of the metal liner layer, and partially filing the recessed feature with a molybdenum metal by a cyclical deposition-etch process, wherein a unit cycle of the cyclical deposition-etch process comprises, partially filing the recessed feature with molybdenum metal by performing one or more unit cycles of a first cyclical deposition process, wherein the first cyclical deposition process deposits a molybdenum metal at a greater deposition rate per cycle proximate to the bottom surface of the recessed feature compared with the deposition rate per cycle proximate to the opening of the recessed feature, and partially etching the molybdenum metal. The methods can further include, filing the recessed feature with additional molybdenum metal by performing one or more unit cycles of a second cyclical deposition process.

In addition to one or more of the processes described above, or as an alternative, further examples may include that a unit cycle of the first cyclical deposition process and a unit cycle of the second cyclical deposition process comprise, contacting the substrate with a first vapor phase reactant comprising a molybdenum oxyhalide, and contacting the substrate with a second vapor phase reactant comprising a reducing agent.

In addition to one or more of the processes described above, or as an alternative, further examples may comprise that the molybdenum oxyhalide is molybdenum (IV) dichloride dioxide (MoO₂Cl₂).

In addition to one or more of the processes described above, or as an alternative, further examples may include that removing at least a portion of the metal liner layer further comprises, contacting the metal liner layer with a gaseous chloride based etchant.

In addition to one or more of the processes described above, or as an alternative, further examples may comprise that contacting the metal liner layer with the gaseous chloride based etchant further comprises, preferentially removing a greater portion of the metal liner layer proximate to the opening of the recessed feature compared with the portion of the metal liner layer removed proximate to the bottom of the recessed feature.

In addition to one or more of the processes described above, or as an alternative, further examples may include that the gaseous chloride based etchant comprises at least of one molybdenum pentachloride (MoCl₅), and tungsten pentachloride (WCl₅).

In addition to one or more of the processes described above, or as an alternative, further examples may include that the metal liner layer comprises a metal nitride liner layer.

In addition to one or more of the processes described above, or as an alternative, further examples may include that partially filing the recessed feature with a molybdenum metal by a cyclical deposition-etch process further comprises, preferentially forming a greater thickness of the molybdenum metal proximate to the bottom of the recessed feature compared with the thickness of the molybdenum metal formed proximate to the opening of the recessed feature.

In addition to one or more of the processes described above, or as an alternative, further examples may include that the first cyclical deposition process employed in the cyclical deposition-etch process deposits a molybdenum metal at a greater deposition rate proximate to the bottom of the recessed feature compared with deposition rate of the molybdenum metal proximate to the opening of the recessed feature.

In addition to one or more of the processes described above, or as an alternative, further examples may include that partially filing and subsequently filing the recessed feature with molybdenum metal and additional molybdenum metal further comprises, seamlessly filling the recessed feature.

In addition to one or more of the processes described above, or as an alternative, further examples may include a structure formed according to the methods outlined herein.

Methods for seamlessly filling a recessed feature on a substrate with a molybdenum metal are provided. The methods can comprise, providing a substrate including a recessed feature, the recessed feature comprising an opening as well as sidewalls and a bottom surface covered with a metal nitride liner. The methods can also include, preferentially etching the metal nitride liner proximate to the opening of the recessed feature, wherein the etch rate of the metal nitride liner proximate to the opening of the recessed feature is up to 300% greater than the etch rate of the metal nitride liner proximate to the bottom surface of the recessed feature. The methods can further include, partially filing the recessed feature with a molybdenum metal by a cyclical deposition-etch process, wherein the cyclical deposition-etch process preferentially forms a molybdenum metal proximate to the bottom surface of the recessed feature. The methods can further include, filing the recessed feature with additional molybdenum metal by performing one or more unit cycles of a cyclical deposition process.

In addition to one or more of the processes described above, or as an alternative, further examples may include that preferentially etching the metal nitride liner further comprises, contacting the metal nitride liner with a gaseous chloride based etchant.

In addition to one or more of the processes described above, or as an alternative, further examples may include that the chloride based etchant comprises at least one of molybdenum pentachloride (MoCl₅), and tungsten pentachloride (WCl₅).

In addition to one or more of the processes described above, or as an alternative, further examples may include that preferentially etching the metal nitride liner layer further comprises, etching the metal nitride liner proximate to the opening of the recessed feature at a higher etch rate compared with the etch rate of the metal nitride liner proximate to the bottom of the recessed feature.

In addition to one or more of the processes described above, or as an alternative, further examples may include that the etch rate of the metal nitride liner proximate to the opening of the recessed feature is up to 300% greater than the etch rate of the metal nitride liner proximate to the bottom surface of the recessed feature.

In addition to one or more of the processes described above, or as an alternative, further examples may include that the metal nitride liner proximate to the opening of the recessed feature is preferentially etched to a thickness of less than 5 Angstroms.

In addition to one or more of the processes described above, or as an alternative, further examples may include that the metal nitride liner comprises at least one of a titanium nitride liner, and a tantalum nitride liner.

In addition to one or more of the processes described above, or as an alternative, further examples may include a structure formed according to any of methods disclosure herein.

In addition to one or more of the processes described above, or as an alternative, further examples may include an apparatus configured for performing any of the method as disclosed herein.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a cross-sectional schematic diagram of a recessed feature filled with a metal that includes a seam feature;

FIG. 2 illustrates an exemplary method in accordance with the embodiments of the disclosure;

FIG. 3 illustrates an exemplary method, demonstrating a cyclical deposition-etch process according to the embodiments of the disclosure;

FIG. 4 is a graph demonstrating a relationship between molybdenum metal deposition rate and the thickness of the underlying metal liner layer;

FIGS. 5-9 illustrate cross-sectional schematic diagrams of structures formed according to the embodiments of the disclosure; and

FIG. 10 illustrates an exemplary apparatus configured for performing the methods described herein, according to the embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, a “precursor” includes a gas or a material that can become gaseous and that can be represented by a chemical formula that includes an element which may be incorporated during a deposition process as described herein.

As used herein, a “structure” can be or include a substrate as described herein. Structures can include one or more layers overlying or within the substrate, such as one or more layers formed according to a method as described herein. Full devices or partial device portions can be included within or on structures.

As used herein, the term “molybdenum halide precursor” may refer to a precursor which comprises at least a molybdenum component and a halide component, wherein the halide component may include one or more of a chlorine component, an iodine component, or a bromine component.

As used herein, the term “molybdenum oxyhalide precursor” may refer to a precursor which comprises at least a molybdenum component, an oxygen component, and a halide component.

As used herein, the terms “recessed feature” and “gap featured” are used interchangeably and may refer to an opening or cavity disposed between surfaces of a non-planar surface. For example, the term “recessed feature” may refer to an opening or cavity disposed between opposing sidewalls or protrusions extending vertically from the surface of a substrate or opposing inclined sidewalls of an indentation extending vertically into the surface of a substrate.

As used herein, the term “seam” may refer to a void line or one or more separated voids formed by the abutment of edges formed in a gap-fill metal. The presence of a “seam” can be confirmed using high magnification microscopy methods, such as, for example, scanning transmission electron microscopy (STEM), and transmission electron microscopy (TEM), wherein if observations reveals a clear vertical void line or one or more vertical voids in a recessed feature filled with a gap-fill metal then a “seam” is deemed to be present.

A number of example materials are given throughout the embodiments of the current disclosure, it should be noted that the chemical formulas given for each of the example materials should not be construed as limiting and that the non-limiting example materials given should not be limited by a given example stoichiometry.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The present disclosure includes methods for filling a recessed feature on a substrate and particularly discloses methods for seamless filling (i.e., without the formation of a seam) a recessed feature with a molybdenum metal by employing preferential etching processes in conjunction with cyclical deposition-etch processes.

Molybdenum metal may be utilized in a number of applications, such as, for example, low electrical resistivity gap-fill, liner layers for 3D-NAND, DRAM word-line features, or as an interconnect material in CMOS logic applications. The ability to deposit a molybdenum metal in a recessed feature can allow for lower effective electrical resistivity for interconnects in logic applications, i.e., CMOS structures, and word-line/bit-line in memory applications, such as 3D-NAND and DRAM structures.

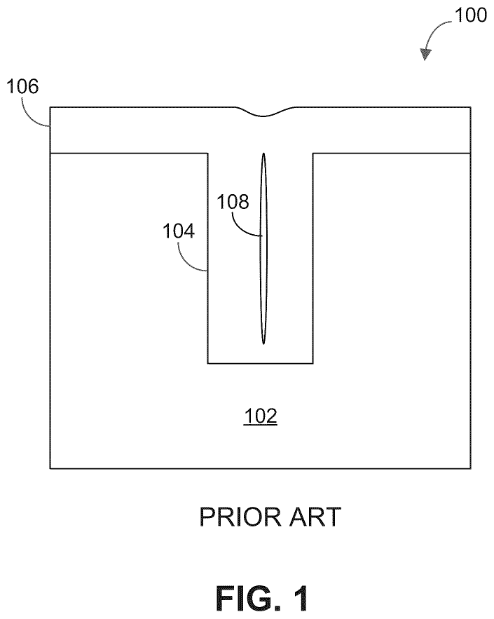

The embodiments of the disclosure may provide gap-fill processes and gap-fill metals which are superior to those previous known. An examples of a structure including a recessed feature filled with a metal by previously known methods is illustrated in FIG. 1.

In more detail, FIG. 1 illustrates a simplified cross-sectional view of a structure 100 including a substrate 102 with a recessed feature 104 filled with a metal 106. Disposed within the metal 106 is a seam 108. The seam can comprise a region in the metal 106 where the edges of films, growing from the sidewalls of the recessed feature, prematurely touch each other. Therefore the seam 108 is commonly disposed near, or at the center, of the recessed feature 104. The formation of a seam 108 in the metal 106 is undesirable as it can result in poor device performance as well as possible issues in device fabrication. In this example, the seam 108 may comprises a vertical line void that may be observable using scanning transmission electron microscopy (STEM) or transmission electron microscopy (TEM) or the like.

Accordingly, methods and structures are desirable that enable the filling of a recessed feature on a substrate with a metal (e.g., a molybdenum metal) without the formation of a seam.

Therefore, the embodiments of the present disclosure may include methods for filling a recessed feature on a substrate. The methods of the present disclosure can include: providing a substrate including a recessed feature, wherein the recessed feature can comprise sidewalls, a bottom surface, and an opening, as well as a metal liner layer disposed over at least the sidewalls, and the bottom surface. The methods may further include, removing at least a portion of the metal liner layer, and partially filing the recessed feature with a molybdenum metal by a cyclical deposition-etch process, wherein a unit cycle of the cyclical deposition-etch process can include, partially filing the recessed feature with a molybdenum metal by performing one or more unit cycles of a first cyclical deposition process, and partially etching the molybdenum metal. The method can further include, filing the recessed feature with additional molybdenum metal by performing one or more unit cycles of a second cyclical deposition process.

The processes of the present disclosure may be performed in reactors and associated reaction chambers configured for performing etch processes, cyclical deposition processes, as well as cyclic deposition-etch processes. Therefore, reactors suitable for performing the processes of the present disclosure may include ALD reactors, as well as CVD reactors, configured to provide the appropriate etchants, precursors, and/or reactants. According to some embodiments, a showerhead reactor may be used. According to some embodiments, cross-flow, batch, minibatch, or spatial ALD reactors may be used.

In some embodiments of the disclosure, a batch reactor may be used. In some embodiments, a vertical batch reactor may be used. In other embodiments, a batch reactor comprises a minibatch reactor configured to accommodate 10 or fewer wafers, 8 or fewer wafers, 6 or fewer wafers, 4 or fewer wafers, or 2 or fewer wafers. In some embodiments in which a batch reactor is used, wafer-to-wafer non-uniformity is less than 3% (1 sigma), less than 2%, less than 1%, or even less than 0.5%.

The exemplary process of the present disclosure may optionally be carried out in a reactor and associated reaction chambers connected to a cluster tool. In a cluster tool, because each reaction chamber is dedicated to one type of process, the temperature of the reaction chamber in each module can be kept constant, which improves the throughput compared to a reactor in which the substrate is heated up to the process temperature before each run. Additionally, in a cluster tool it is possible to reduce the time to pump the reaction chamber to the desired process pressure levels between substrates. The exemplary processes of the present disclosure may be performed in a cluster tool comprising multiple reaction chambers, wherein each individual reaction chamber may be utilized to expose the substrate to an individual precursor gas and the substrate may be transferred between different reaction chambers for exposure to multiple precursors gases, the transfer of the substrate being performed under a controlled ambient to prevent oxidation/contamination of the substrate. For example, the etching processes and cyclic deposition-etch processes described herein may be performed in separate reaction chambers of the cluster tool with the transfer back and forth between the two reaction chambers taking place under a controlled environment to prevent contamination or degradation of the substrate and associated metal films.

In some embodiments, the processes of the present disclosure may be performed in a single stand-alone reactor which may be equipped with a load-lock. In that case, it is not necessary to cool down the reaction chamber between each run.

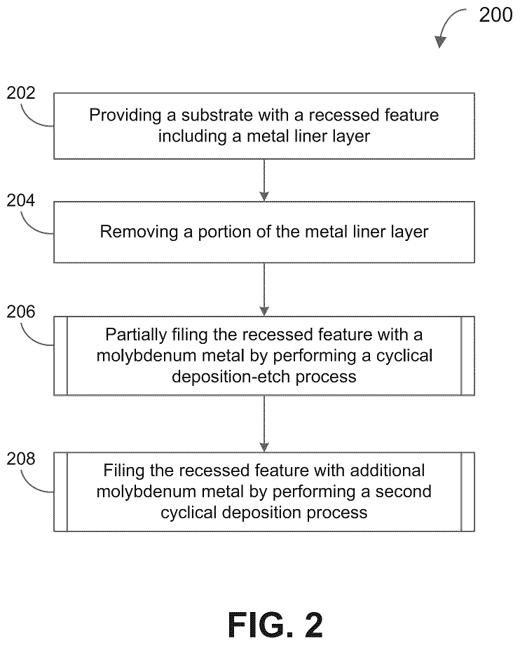

An exemplary method 200 for filling a recessed feature on a substrate according to the embodiments of the present disclosure is illustrated with reference FIG. 2. Briefly, method 200 can include the steps of, providing a substrate with a recessed feature including a metal liner layer (step 202), removing a portion of the metal liner layer (step 204), partially filing the recessed feature with molybdenum metal by performing a cyclical deposition-etch process (step 206), and filing the recessed feature with additional molybdenum metal by performing a cyclical deposition process (step 208).

In more detail, the exemplary process 200 includes step 202 which comprises, providing a substrate including a recessed feature. In some embodiments, the recessed feature comprises, one or more sidewalls, a bottom surface, an opening, and a metal liner layer disposed over at least the sidewalls, and the bottom surface.

In some embodiments of the disclosure, the substrate may comprise a patterned substrate including a number of high aspect ratio recessed features, such as, for example, trench structures, vertical gaps, and/or fin structures. The substrate may comprise a plurality of recessed features having an aspect ratio (height:width) greater than 2:1, or greater than 5:1, or greater than 10:1, or greater than 25:1, or greater than 50:1, or even greater than 100:1, wherein “greater than” as used in this example refers to a greater height of the recessed feature. The substrate may comprise one or more materials and material surfaces including, but not limited to, semiconductor materials, dielectric materials, and metallic materials.

Substrates can further include device structures formed into or onto a surface of the substrate. For example, a patterned substrate may comprise partially fabricated device structures, such as, for example, transistors and/or memory elements, and such. In such embodiments, the partially fabricated device structures can include a plurality of recessed features.

In some embodiment of the disclosure, a recessed feature on a substrate may be covered at least in part by a metal liner layer. For example, a metal liner layer may be deposited over the recessed feature and covers at least the sidewalls of the recessed feature, as well as the bottom surface of the recessed feature.

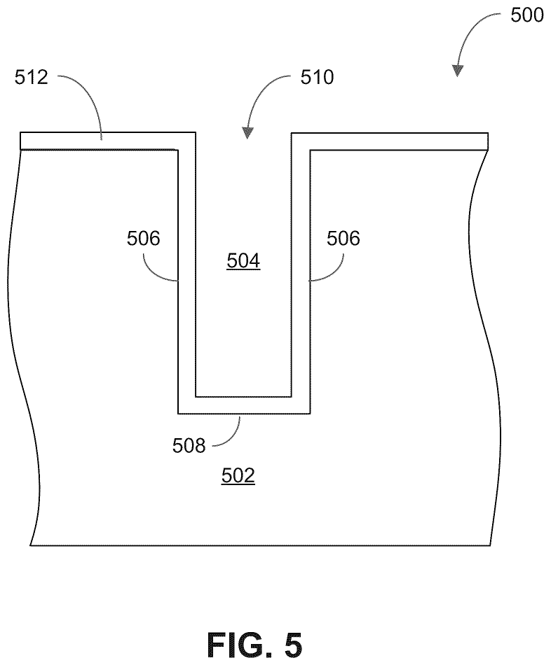

As a non-limiting example, FIG. 5 illustrates an exemplary structure 500, which comprises a portion of a substrate 502 including a recessed feature 504 and a metal liner layer 512. In this example, the recessed feature 504 comprises a high aspect ratio vertical trench. The recessed feature 504 includes sidewalls 506, a bottom surface 508, and an opening 510. It should be noted that the recessed feature 504 illustrated in FIG. 5 is exemplary and the methods disclosed herein encompass seamless filing of recessed features with alternative profiles, including, but not limited to, curved, scalloped, V-shaped, tapered, re-entrant, as well as through-silicon-via trenches. In addition, the bottom surface 508 as illustrated in FIG. 5 may have alternative profiles other than the horizontal bottom surface exemplified in FIG. 5. For example, the bottom surface may be curved, arched, V-shaped, etc., with the bottom surface simply being defined as the lowest surface region of the recessed feature.

In some embodiments, the metal liner layer 512 may comprise a metal nitride liner layer, for example, a titanium nitride liner, or a tantalum nitride liner. Metal liner layer 512 may be employed for a number purposes. For example, the metal liner layer 512 may be employed to promote deposition or adhesion of a subsequent gap-fill metal within the recessed feature 504. In addition or alternatively, the metal liner layer 512 may be employed as a diffusion barrier to prevent diffusion of a subsequent gap-fill metal within the recessed feature 504 into the surrounding substrate 502.

Returning to the exemplary process 200 (FIG. 2) of the present disclosure, the process 200 may continue by removing a portion of the metal liner layer (step 204).

In more detail, the embodiments of the present disclosure have found that filling a recessed feature including a metal liner with a non-uniform thickness promotes seamless gap-fill. In particular, forming a gap-fill metal over a metal liner layer which has a greater thickness proximate to the bottom surface of the recessed feature compared to the thickness of the metal liner layer proximate to the opening of the recessed feature allows for the subsequent seamless filling of the recessed feature.

Therefore, the embodiments of the disclosure, preferentially remove the metal liner layer proximate to the opening of the recessed feature in comparison to the amount of metal liner layer removed proximate to the bottom surface of the recessed feature. In some embodiments, a preferential etch of the metal liner proximate to the opening of the recessed feature may be achieved by contacting the metal liner with a gaseous etchant, wherein the gaseous etchant preferentially etches the upper portions of the metal liner layer (proximate to the recessed feature opening) compared with the lower portions of the metal liner layer (proximate to the bottom surface of the recessed feature). This non-homogenous etch rate may be due in part to a lower concentration of the gaseous etchant proximate to the bottom surface resulting from the need for the gaseous etchant to diffuse over a greater distance to contact the lower portions of the recessed feature.

Therefore, in some embodiments of the disclosure, removing a portion of the metal liner layer may comprise contacting the metal liner layer with a chloride based etchant. In some embodiment, removing a portion of the metal liner may comprise contacting the metal liner with a gaseous chloride based etchant. For example, the metal liner layer may be contacted with a gaseous chloride based etchant comprising at least one of molybdenum pentachloride (MoCl₅), and tungsten pentachloride (WCl₅).

In some embodiments of the disclosure, removing a portion of the metal liner layer may comprise a cyclical etch-purge process, wherein the metal liner layer is contacted with a gaseous chloride based etchant for a period of time and subsequently excess gaseous chloride based etchant (and any possible reaction byproducts) are purged from the reaction chamber, e.g., by introducing a purge gas and/or pumping the reaction chamber to vacuum. Therefore a unit cycle of the cyclical etch-purge process can comprise, contacting the substrate (and particularly the metal liner layer) with a gaseous chloride based etchant for a period of time, and subsequently purging the reaction chamber (and the recessed feature disposed therein) of excess etchant and any reaction byproducts. The cyclical etch-purge can be repeated one or more time until a desired portion of the metal liner layer has been preferentially etched. For example, a unit cycle of the cyclical etch-purge process may include contacting the substrate (and particular the metal liner layer) with a gaseous chloride based etchant for a time period of less than 30 seconds, or less than 15 seconds, or less than 8 seconds, or less than 4 seconds, or less than 1 seconds, or less than 0.1 seconds, or between 0.1 seconds and 30 seconds. Upon completing the etch step, the reaction chamber can be purged as known in the art, e.g., by introducing an inert purge gas and/or evacuating the reaction chamber to a pumping system.

In some embodiment, removing a portion of the metal liner may comprise, preferentially etching the metal liner layer (e.g., a metal nitride liner) proximate to the opening of the recessed feature. Preferentially etching the metal liner layer may further comprise, etching the metal liner layer proximate to the opening of the recessed feature at a higher etch rate compared with the etch rate of the metal liner layer proximate to the bottom surface of the recessed feature. In some embodiments, the etch rate of the metal liner layer proximate to the opening of the recessed feature can be greater than 50%, or greater 100%, or greater 150%, or greater than 250%, or even greater than 300%, greater than the etch rate of the metal liner layer proximate to the bottom surface of the recessed feature.

In some embodiments, the preferential etching of the metal liner layer may be performed by contacting the metal liner layer with the gaseous chloride based etchant at a substrate temperature less than 600° C., or less than 500° C., or less than 400° C., or less than 300° C., or less than 200° C., or even less than 100° C. In some embodiments, the preferential etching of the metal liner layer proximate to the opening of the recessed feature may be performed by contacting the metal liner layer with the gaseous chloride based etchant at a temperature between 100° C. and 600° C., or between 200° C. and 500° C., or even between 300° C. and 450° C.

In some embodiments, the metal liner layer may have an initial thickness (prior to etching) of less than 50 Angstroms, or less than 40 Angstroms, or less than 30 Angstroms, or less than 20 Angstroms, or less than 10 Angstroms, or between 10 Angstroms and 50 Angstroms. Upon preferential etching of the metal liner layer, the metal liner layer proximate to the opening of the recessed feature may have a thickness less than 20 Angstroms, or less than 10 Angstroms, or less than 5 Angstroms, or may even be completely removed.

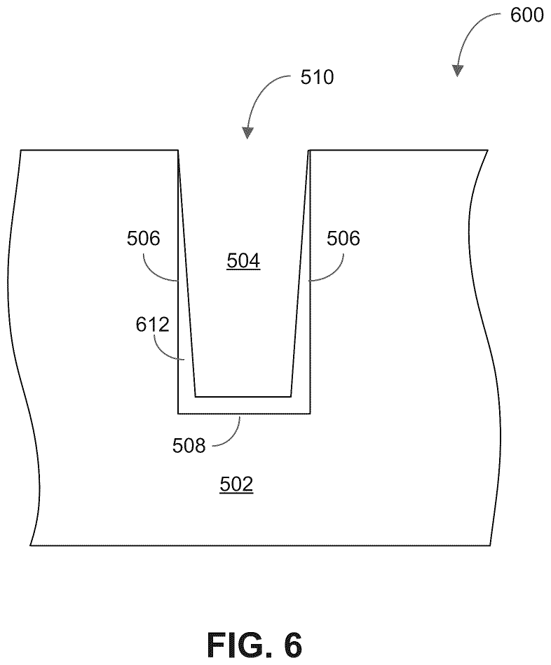

The preferential etching of the metal liner layer can result in a metal liner layer within the recessed feature which has a tapered profile. As a non-limiting example, FIG. 6 illustrates a structure 600 which comprises the previously described structure 500 (FIG. 5) having subsequently been contacted with the gaseous chloride based etchant. As illustrated in FIG. 6, the post-etch structure 600 includes a metal liner layer 612 which has a greater thickness proximate to the bottom surface 508 compared to the thickness of the metal liner layer 612 proximate to the opening of the recessed feature 510, resulting in the metal liner layer 612 having a tapered profile. It should be noted that the profile of the metal liner layer 612 illustrated in FIG. 6 is exemplary and that other profiles may be achieved, although the resulting profiles can have the characteristic of a greater thickness of the metal liner layer in proximity to the bottom surface 508 of the recessed feature in comparison to the thickness of the metal liner layer proximate to the opening of the recessed feature 510.

Upon removing a portion of the metal liner layer, the exemplary process 200 (FIG. 2) of the present disclosure may continue with step 206 which comprises, partially filing the recessed feature with a molybdenum metal by performing a cyclical deposition-etch process, wherein a unit cycle of the cyclical deposition-etch process includes, partially filing the recessed feature with molybdenum metal by performing one or more unit cycles of a first cyclical deposition process, and partially etching the molybdenum metal.

In some embodiments, the cyclical deposition-etch step (206) may be performed at a constant substrate temperature. In alternative embodiments, the substrate may be heated to a first substrate temperature for the deposition stage and a second substrate temperature for the etch stage of the cyclical deposition-etch phase.

In some embodiments of the disclosure, the substrate may be heated to a substrate temperature of less than 800° C., or less than 700° C., or less than 600° C., or less than 500° C., or less than 400° C., or less than 300° C., or even less than 200° C. In some embodiments of the disclosure, the substrate may be heated to a process temperature for exemplary process 200 of between 200° C. and 800° C., or between 300° C. and 700° C., or between 400° C. and 600° C., or between 525° C. and 575° C.

In addition to achieving a desired substrate temperature, the pressure within the reaction chamber may also be controlled to obtain an optimal cyclical deposition-etch process. For example, in some embodiments of the disclosure, the cyclical deposition-etch step 206 may be performed within a reaction chamber regulated to a reaction chamber pressure of less than 300 Torr, or less than 200 Torr, or less than 100 Torr, or less than 50 Torr, or less than 25 Torr, or even less than 10 Torr. In some embodiments, the pressure within the reaction chamber during the cyclical deposition-etch process 206 may be regulated at a pressure between 10 Torr and 300 Torr, or between 20 Torr and 80 Torr, or between 40 Torr and 50 Torr, or even equal to or greater than 20 Torr.

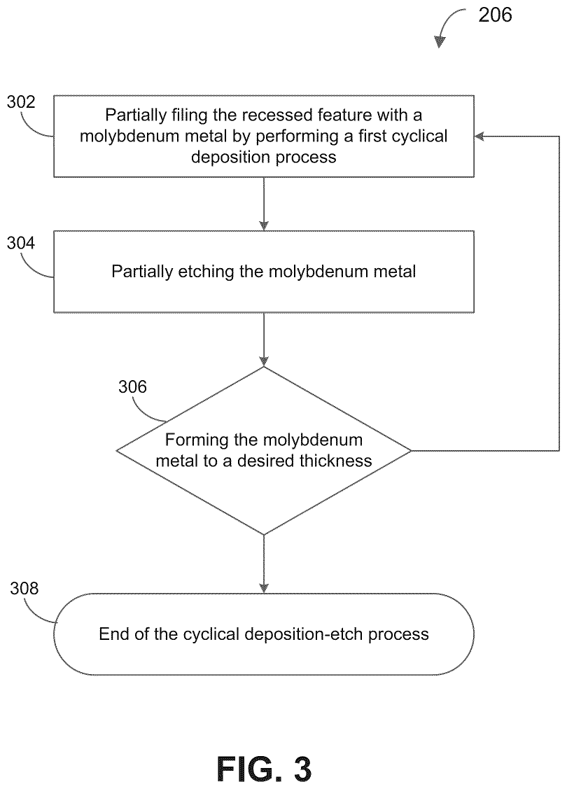

The cyclical deposition-etch process (step 206) is illustrated in greater detail with reference to FIG. 3 which illustrates the sub-steps of the cyclical deposition-etch process. Further details regarding a cyclical deposition-etch process employed for filling a recessed feature are described in U.S. Patent Publication No. US 20190067014 (herein after referred to as the 7014 reference), the entire contents of which are incorporated by reference herein in their entirety and for all purposes. Therefore, the following briefly describes the cyclical deposition-etch process and focuses on the alternative and additional features and processes of the present disclosure.

The cyclical deposition-etch process 206 (FIG. 3) may comprise, partially filing the recessed feature with a molybdenum metal by performing a first cyclical deposition process (sub-step 302), and subsequently partially etching the molybdenum metal (sub-step 304). Therefore a unit cycle of the cyclical-deposition etch process 206 comprises the sub-steps 302 and 304, with possible intervening purge cycles to remove excess precursors, reactants, and any reaction byproducts.

The cyclical deposition-etch process can be repeated a number of times until a desired thickness of molybdenum metal partially fills the recessed feature. For example the cyclical deposition-etch process 206 (FIG. 3) includes the decision gate (sub-step 306) wherein if the cyclical deposition-etch sub-steps 302 and 304 have not achieved the desired partially fill thickness of molybdenum metal within the recessed feature then further cycles can be performed by repeatedly returning to sub-steps 302 and 304, with possible intervening purge cycles between sub-steps 302 and 304.

The cyclical deposition-etch process 206 (FIG. 3) can commence by partially filing the recessed feature with a molybdenum metal by performing a first cyclical deposition process (sub-step 302). For example, the first cyclical deposition process may comprise an atomic layer deposition (ALD) process, or a cyclical chemical vapor deposition (CCVD) process. The details of the cyclical deposition processes are described in the 7014 reference and are therefore only briefly summarized herein.

The first cyclical deposition process may comprise, contacting the substrate with a first vapor phase reactant comprising a molybdenum precursor, and contacting the substrate with a second vapor phase reactant comprising a reducing agent. The first cyclical deposition cycle can also include intervening purge cycles to remove excess precursor, reactants, as well any reaction byproducts.

In some embodiments, the molybdenum precursor may comprise a molybdenum chloride, such as, for example, molybdenum pentachloride (MoCl₅). In other embodiments, the molybdenum precursor may comprise a molybdenum oxyhalide, such as, for example, molybdenum (IV) dichloride dioxide (MoO₂Cl₂).

In some embodiments, the reducing agent may comprise at least one of molecular hydrogen (H₂), hydrogen atoms (H), a hydrogen plasma, hydrogen radicals, hydrogen excited species, an alcohol, an aldehyde, a carboxylic acid, or a borane. In further embodiments, the reducing agent may comprise at least one of silane (SiH₄), disilane (Si₂H₆), trisilane (Si₃H₈), germane (GeH₄), digermane (Ge₂H₆), borane (BH₃), or diborane (B₂H₆).

A unit cycle of the first cyclical deposition process can therefore comprise, contacting the substrate with a molybdenum oxyhalide precursor, purging the reaction chamber, contacting the substrate with a reducing agent, and again purging the reaction. The unit cycle can be repeated a number of times to deposit a desired thickness of molybdenum metal to partially fill the recessed feature on the substrate. In some embodiments, the first cyclical deposition cycle may be repeated to deposit a molybdenum metal with an average film thickness of less than 50 Angstroms, or less than 40 Angstroms, or less than 30 Angstroms, or less than 20 Angstroms, or less than 10 Angstroms, or between 1 and 50 Angstroms, or between 5 and 25 Angstroms, or even between 5 and 15 Angstroms.

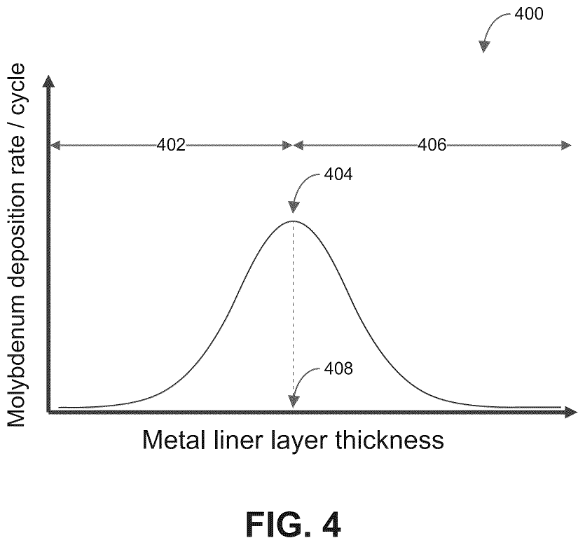

The embodiments of the present disclosure have found that the cyclical deposition rate (i.e., the amount of deposition per deposition cycle) of molybdenum metal varies depending on the thickness of the underlying metal liner layer. FIG. 4 illustrates graph 400 which demonstrates the relationship between the deposition rate per cycle of a molybdenum metal on an underlying metal liner layer as a function of the thickness of the metal liner layer. Referring to graph 400, the deposition rate per cycle of the molybdenum metal initially increases with increasing thickness of the underlying metal liner layer, as illustrated by the first deposition regime 402. The deposition rate per cycle of the molybdenum metal then reaches a peak deposition rate 404 corresponding to a metal liner layer thickness 408. Increasing the metal liner thickness beyond the metal liner thickness 408 results in a decrease in the deposition rate per cycle of molybdenum metal, as illustrated by the second deposition regime 406.

As non-limiting examples of the present disclosure, the peak in molybdenum metal deposition rate per cycle (404) may occur for a metal liner layer thickness of approximately 15 Angstroms which can correspond to a peak deposition rate of 0.8 Angstroms per cycle for the molybdenum metal. Therefore, in this non-limiting example, the first deposition regime 402 extends from between 0 Angstroms up to approximately 15 Angstroms thickness of the metal liner layer. Whereas, the second deposition regime 406 extends for a metal liner layer with a thickness greater than 15 Angstroms. It should be noted the peak deposition rate per cycle and the corresponding thickness of the metal liner layer at which this occurs can be process dependent as well as materials dependent and the examples given herein are given purely for demonstrating the novel processes of the present disclosure.

Therefore the embodiments of the present disclosure employ a metal liner layer with a non-homogenous thickness. For example, the thickness of the metal liner can vary (i.e., increase or decrease) as function of the depth within the recessed feature. In some embodiments, the varying thickness of the metal liner layer can be achieved by the preferential etching of the metal liner layer in proximity to the recessed features opening (as described herein above), to enable a variable deposition rate per cycle of the molybdenum metal within the recessed feature, this variable deposition rate in part enabling the formation of a seamless fill of the recessed feature.

It should also be noted that the disclosed relationship between molybdenum metal deposition rate and the thickness of the underlying metal liner layer may also have additional benefits and applications in the fabrication and processing of semiconductor devices which are not disclosed herein. It should therefore be understood that the embodiments of the present disclosure extend beyond those specifically described herein to other alternative embodiments and/or uses and obvious modifications and equivalents thereof.

In some embodiments, the thickness of the metal liner layer within the recessed feature can be within the first deposition regime (402) and the deposition rate per cycle of the molybdenum metal will correspondingly increase with increasing metal liner thickness up to the peak thickness 408. In other embodiments, the thickness of the metal liner layer within the recessed feature can be within the second deposition regime (406) and the deposition rate per cycle of the molybdenum metal will decrease with increasing metal liner thickness. In some embodiments, a metal liner layer may have a non-uniform thickness and in such instances the thickness of the metal liner layer may lie within both the first deposition regime (402) and the second deposition regime (406) depending on the thickness variation of the metal liner layer. Therefore, metal liner thickness can be employed as a further parameter in controlling the deposition rate of the molybdenum metal and as such can be utilized for depositing a molybdenum metal with preferred characteristics and functions.

As an example of the embodiments of the present disclosure and how they utilize the novel relationship between molybdenum metal deposition rate and metal liner thickness, the structure 600 (FIG. 6) is reviewed. In brief, structure 600 includes the substrate 502 and the recessed feature 504. The recessed feature 504 also includes the metal liner 612 which has a tapered profile resulting from the preferentially etch process as previously described. The variable thickness of the metal liner as a function of depth within the recessed features enables a molybdenum metal to be deposited at different deposition rates within the recessed feature.

As a non-limiting example, when the metal liner 612 has a thickness profile which is within the first deposition regime (402 of FIG. 4) then the molybdenum metal will deposit at a higher deposition rate per cycle proximate to the bottom surface (508) of the recessed feature 504 in comparison to the deposition rate per cycle of the molybdenum metal proximate to the opening 510 of the recessed feature 504. Therefore, for a given number of cyclical deposition cycles, a greater thickness of molybdenum metal can be deposited in proximity to the bottom surface 508 of the recessed feature in comparison to the thickness of molybdenum metal deposited in proximity to the opening of the recessed feature where the metal liner thickness is less.

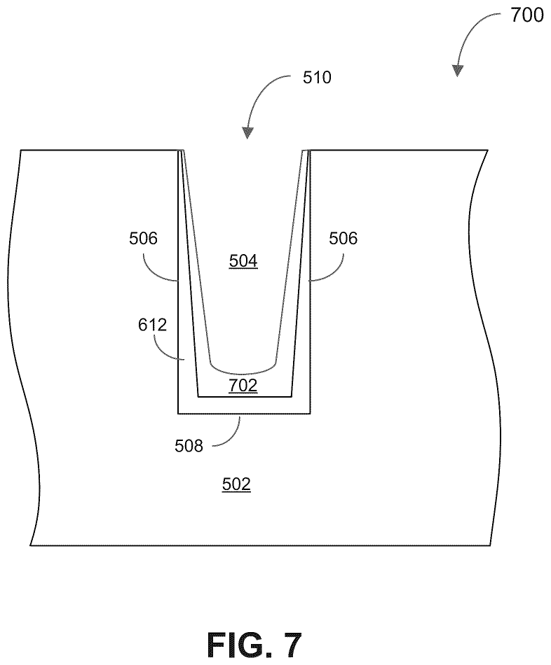

To demonstrate this variation in deposition rate, FIG. 7 illustrates the structure 700 which shows the structure 600 (FIG. 6) after a number of deposition cycles of the first cyclical deposition process have been performed. The resulting molybdenum metal 702 deposited within the recessed feature 702 has a greater thickness proximate to the bottom surface 508 in comparison to the thickness of the molybdenum metal 702 in proximity to the opening 510 of the recessed feature. Therefore the embodiments of the disclosure enable what is commonly referred to as “bottom-up gap-fill” wherein the recessed feature is filled with material initially from the bottom surface of the recessed feature. The benefits of a “bottom-up gap-fill” process can include the mitigation or even elimination of the formation of a seam within the gap-fill material.

In more detail, one of the causes of seam/void formation within a gap-fill material is the premature closure of the gap-fill material within the recessed feature. Premature closure of the gap-fill material, i.e., when the various growth fronts of the gap-fill material make contact with each other prior to completion of filling the recessed feature which can often result in the formation of a seam/voids. Therefore, the bottom-up gap-fill processes as described herein prevent premature closure during the filling process and therefore enable a seamless gap-fill.

To further enable the gap-fill processes of the present disclosure the cyclical-deposition-etch process includes a partial etch of the deposited molybdenum metal. For example, a partial etch of the deposited molybdenum metal within the recessed feature may further mitigate the possibility of premature closure of the molybdenum metal within the recessed feature.

In more detail and with further reference to the cyclical deposition-etch process 206 (FIG. 3), during the partial etching of the molybdenum metal (sub-step 304) the substrate may be maintained at the same process temperature utilized in the first cyclical deposition process (sub-step 302), or alternatively during the partial etching of the molybdenum metal (sub-step 304), the process temperature may be different to that utilized during cyclical deposition (sub-step 302). Details regarding temperatures and pressures for the partial etch process are described in detail in the 7014 reference and therefore not repeated herein.

The partially etching (sub-step 304) of the deposited molybdenum metal may comprise, flowing an etchant gas into the reaction chamber and contacting the molybdenum metal with the etchant gas. In some embodiments, the etchant gas may comprise a gaseous chloride based etchant gas, such as, for example, chlorine vapor (Cl₂), or hydrochloric acid vapor (HCl). In particular embodiments of the disclosure, the gaseous chloride etchant gas may comprise molybdenum pentachloride (MoCl₅), or tungsten pentachloride (WCl₅), for example.

In some embodiments of the disclosure, partially etching the deposited molybdenum metal may comprise contacting the molybdenum metal with the etchant gas for a time period of between about 0.1 seconds and about 30 seconds, between about 0.1 seconds and about 10 seconds, or between about 0.5 seconds and about 5.0 seconds, or even between 1.0 second and 2.0 seconds. In addition, during the partial etching of the molybdenum metal, the flow rate of the etchant gas may be less than 5000 sccm, or less than 1000 sccm, or less than 500 sccm, or even less than 100 sccm.

In some embodiments of the disclosure, partially etching the deposited molybdenum metal may comprise performing one or more cycles of a cyclical etch-purge process, wherein the molybdenum metal is contacted with a gaseous chloride based etchant for a period of time and subsequently excess chloride based etchant (and any possible reaction byproducts) are purged from the reaction chamber, e.g., by introducing a purge gas and/or pumping the reaction chamber to vacuum. Therefore a unit cycle of the cyclical etch-purge process can comprise, contacting the substrate (and particularly the molybdenum metal) with a gaseous chloride based etchant for a period of time, and subsequently purging the reaction chamber (and the recessed feature disposed therein) of excess etchant and any reaction byproducts. The cyclical etch-purge can be repeated one or more time until a desired portion of the molybdenum metal has been removed. For example, a unit cyclical of the cyclical etch-purge process may include contacting the molybdenum metal with a chloride based etchant for a time period of less than 30 seconds, or less than 15 seconds, or less than 8 seconds, or less than 4 seconds, or less than 1 seconds, or less than 0.1 seconds, or between 0.1 seconds and 30 seconds. Upon completing the etch step the reaction chamber can be purged as known in the art, e.g., by introducing an inert purge gas and/or evacuating the reaction chamber to a pumping system.

In some embodiments of the disclosure, the etch rate of the molybdenum metal may be less than 10 Angstroms per second, or less than 8 Angstroms per second, or less than 6 Angstroms per second, or less than 4 Angstroms per second, or less than 2 Angstroms per second, or less than 1 Angstroms per second, or less than 0.5 Angstroms per second, or less than 0.1 Angstroms per second. For example, the partial etching of the molybdenum metal may comprise etching a thickness of the molybdenum metal of less than 20 Angstroms, or less than 10 Angstroms, or even less than 5 Angstroms. In some embodiments, the etchant gas may preferentially etch the deposited molybdenum metal in proximity to the opening of the recessed feature, thereby preventing premature closure and maintaining an open recessed feature for subsequent completion of the fill.

The partial etch (sub-step 304) may continue by purging the reaction chamber. For example, the etchant gas and reaction byproducts (if any) may be removed from the surface of the substrate, e.g., by pumping with an inert gas. Excess gaseous chloride etchant gas and any possible reaction byproducts may be removed with the aid of a vacuum, generated by a pumping system in fluid communication with the reaction chamber.

The cyclic deposition-etch process 206 (FIG. 3) may continue with a decision gate (sub-step 306), wherein the decision gate is dependent on the thickness of the molybdenum metal formed in the recessed feature. For example, if the molybdenum metal is formed at an insufficient thickness, then the cyclical deposition-etch process may be repeated by repeatably returning to sub-steps 302 and 304. As a non-limiting example, the cyclical deposition-etch process may be repeated until the recessed feature is at least 80 percent, or 90 percent, or 95 percent, or even 99 percent filled with a molybdenum metal. Once the desired thickness of molybdenum metal partially fills the recessed feature then the cyclical deposition-etch process is halted as denoted by sub-step 308 of process 206.

Returning to the exemplary process 200 (FIG. 2), once the cyclical deposition-etch process (step 206) has been completed the process 200 may continue with step 208 which comprises, filing the recessed feature with additional molybdenum metal by performing a second cyclical deposition process.

In more detail, the cyclical deposition-etch process (step 206) partially fills the recessed featured with molybdenum metal and a second cyclical deposition process can subsequently be employed to fill the remaining portion of the recessed feature with additional molybdenum metal. The second cyclical deposition process (step 208) may comprise, filling the recessed feature with additional molybdenum metal film by performing one or more unit cycles of a second cyclical deposition process. In some embodiment, the second cyclical deposition process may be the same as the first cyclical deposition process utilized in part to partially fill the recessed feature with a molybdenum metal film. Therefore step 208 is briefly described herein below as this step has been previously described with reference to the cyclical deposition-etch step 206.

Therefore, the substrate including the partially filled recessed feature may be disposed in a reaction chamber configured for at least one of an atomic layer deposition process and/or a cyclical chemical vapor deposition process. In some embodiments, the second cyclical deposition process may comprise an atomic layer deposition process or a cyclical chemical vapor deposition process.

In some embodiments, the process temperatures and pressures utilized for the second cyclical deposition process may be the same as those utilized for the first cyclical deposition process. Details regarding process temperatures and pressures have been described herein above and are therefore not repeated herein.

In some embodiment of the disclosure, filling the recessed feature with additional molybdenum metal by performing one or more unit cycles of a second cyclical deposition process may comprise, contacting the substrate with a molybdenum halide precursor, purging the reaction chamber, contacting the substrate with a reducing agent, and purging the reaction chamber. The molybdenum halide precursor may comprise all of the molybdenum halide precursors as previously described, and in particular embodiments, the molybdenum halide precursor may comprise a molybdenum oxyhalide, such as, molybdenum (IV) dichloride dioxide (MoO₂Cl₂). The reducing agent may comprise one or more of the reducing agent previously described, and in particular embodiments, the reducing agent may comprise molecular hydrogen (H₂).

A number of cycles of the second cyclical deposition process 208 may be performed until the recessed feature is satisfactory filled with additional molybdenum metal. The substrate with the filled recessed feature may then be subjected to further processes to complete the desired device structure.

In some embodiments of the disclosure, the additional molybdenum metal deposited by step 208 may completely fill the remaining portion of the recessed feature. For example, in some embodiments, the second cyclical deposition process may fill at least 20 percent, or 15 percent, or 10 percent, or 5 percent, or even 1 percent of the recessed feature thereby completing the fill of the recessed feature with molybdenum metal.

In some embodiments of the disclosure, further molybdenum metal may be optionally deposited once the recessed feature has been completely filled. This further molybdenum metal is commonly referred to as “overburden” and may be deposited by further repeated cycles of the second cyclical deposition process. For example, the further “overburden” molybdenum metal may be deposited to an average thickness of less than 200 Angstroms, or less than 100 Angstroms, or less than 50 Angstroms, or less than 25 Angstroms, or between 200 Angstroms and 25 Angstroms.

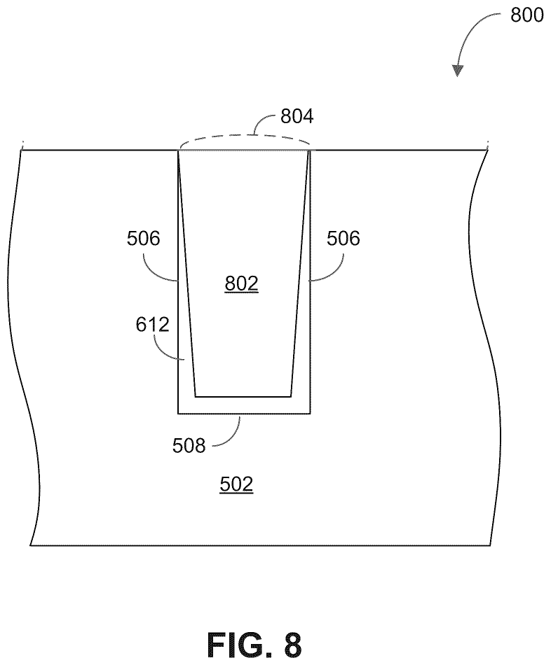

FIG. 8 illustrates a structure 800 which comprises the previous structure 700 (FIG. 7) upon completion of the second cyclical deposition process (step 208). As illustrated in FIG. 8 the molybdenum metal 802 completely fills the recessed feature without the formation of a seam or voids within the molybdenum gap-fill metal. Also illustrated in FIG. 8 is an optional overburden molybdenum film 804, deposited as described herein above.

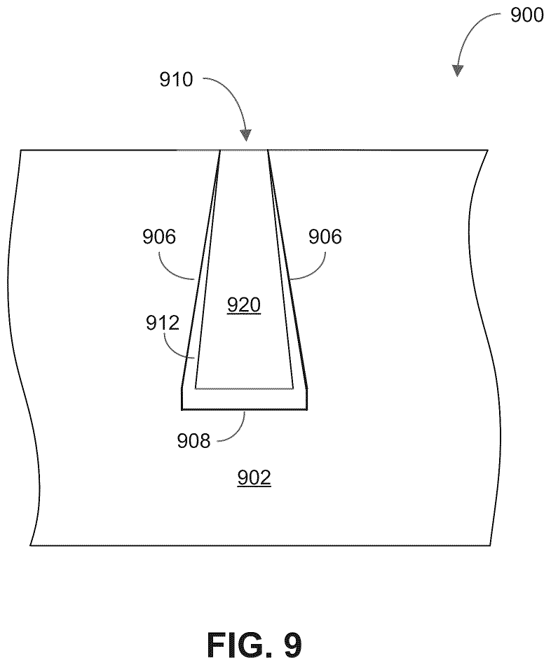

The methods and particularly the process steps outlined herein are not limited to one particular profile of recessed feature but may be employed for seamlessly filling recessed features with a multitude of profiles. As a non-limiting example, FIG. 9 illustrates a structure 900 which includes a seamlessly filled recessed feature with a re-entrant profile. Referring to FIG. 9, a substrate 902 includes a recessed feature with a re-entrant profile including sidewalls 906 and a bottom surface 908. A metal liner layer 912 has been preferentially etched according to the embodiments of the present disclosure to produce a metal liner layer 912 with a greater thickness proximate to the bottom surface 908 in comparison to the thickness of the metal liner layer 912 proximate to the upper surface 910 of the re-entrant recessed feature. A gap-fill of molybdenum metal 920 completely fills the re-entrant recessed feature without the formation of a seam.

Embodiments of the present disclosure may also include an apparatus configured for performing the exemplary methods of the present disclosure, including etch processes, cyclical deposition processes, and cyclical deposition-etch processes.

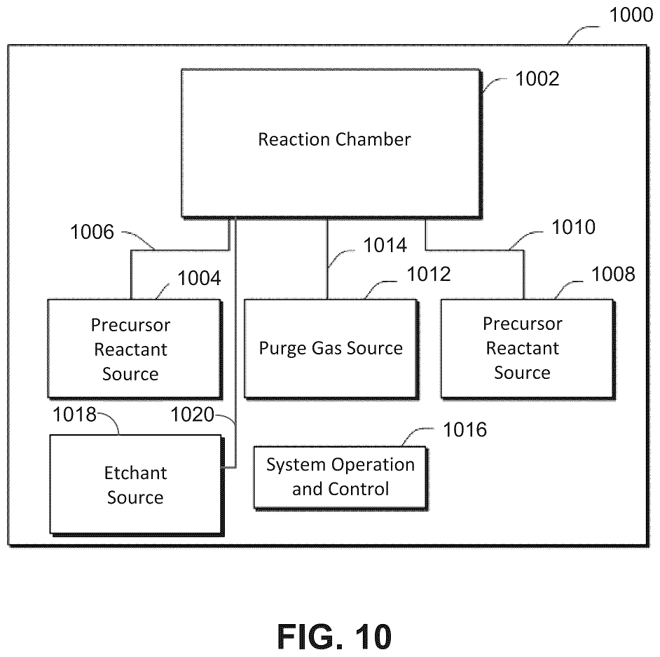

In more detail, FIG. 10 schematically illustrates a reaction system 1000 including a reaction chamber 1002 that further includes mechanism for retaining a substrate (not shown) under predetermined pressure, temperature, and ambient conditions, and for selectively exposing the substrate to various gases. A precursor reactant source 1004 may be coupled by conduits or other appropriate means 1006 to the reaction chamber 1002, and may further couple to a manifold, valve control system, mass flow control system, or mechanism to control a gaseous precursor originating from the precursor reactant source 1004. A precursor (not shown) supplied by the precursor reactant source 1004, the reactant (not shown), may be liquid or solid under room temperature and standard atmospheric pressure conditions. Such a precursor may be vaporized within a reactant source vacuum vessel, which may be maintained at or above a vaporizing temperature within a precursor source chamber. In such embodiments, the vaporized precursor may be transported with a carrier gas (e.g., an inactive or inert gas) and then fed into the reaction chamber 1002 through conduit 1006. In other embodiments, the precursor may be a vapor under standard conditions. In such embodiments, the precursor does not need to be vaporized and may not require a carrier gas. For example, in one embodiment the precursor may be stored in a gas cylinder. For example, the precursor reactant source 1004 may be constructed and configured for supplying a molybdenum oxyhalide precursor to the reaction chamber 1002.

The reaction system 1000 may also include additional precursor reactant sources, such as a precursor reactant source 1008 which may also be coupled to the reaction chamber by conduits 1010 as described above. For example, the precursor reactant source 1008 may be constructed and configured for supplying a reducing agent to the reaction chamber 1002. In addition, the reaction system 1000 may also include a etchant source 1018 which may be coupled to the reaction chamber 1002 by conduits 1020. For example, the etchant source 1018 may be constructed and configured for supplying a gaseous chloride etchant to the reaction chamber 1002.

A purge gas source 1012 may also be coupled to the reaction chamber 1002 via conduits 1014, and selectively supplies various inert or noble gases to the reaction chamber 1002 to assist with the removal of precursor/reactant/etchant gas or waste gases from the reaction chamber. The various inert or noble gases that may be supplied may originate from a solid, liquid or stored gaseous form.

The reaction system 1000 of FIG. 10, may also comprise a system operation and control mechanism 1016 that provides electronic circuitry and mechanical components to selectively operate valves, manifolds, pumps and other equipment included in the reaction system 1000. Such circuitry and components operate to introduce precursors, purge gases from the respective precursor sources 1004, 1008, 1018, and purge gas source 1012. The system operation and control mechanism 1016 also controls timing of gas pulse sequences, temperature of the substrate and reaction chamber 1002, and pressure of the reaction chamber 1002 and various other operations necessary to provide proper operation of the reaction system 1000. The operation and control mechanism 1016 can include control software and electrically or pneumatically controlled valves to control flow of precursors, etchants, reactants and purge gases into and out of the reaction chamber 1002. The control system 1016 can include modules such as a software or hardware component, e.g., a FPGA or ASIC, which performs certain tasks. A module can advantageously be configured to reside on the addressable storage medium of the control system and be configured to execute one or more processes.

Those of skill in the relevant arts appreciate that other configurations of the present reaction system are possible, including a different number and kind of precursor reactant sources and purge gas sources. Further, such persons will also appreciate that there are many arrangements of valves, conduits, precursor sources, purge gas sources that may be used to accomplish the goal of selectively feeding gases into reaction chamber 1002. Further, as a schematic representation of a reaction system, many components have been omitted for simplicity of illustration, and such components may include, for example, various valves, manifolds, purifiers, heaters, containers, vents, and/or bypasses.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for filling a recessed feature on a substrate, the method comprising:
providing a substrate including a recessed feature; the recessed feature comprising;
sidewalls, a bottom surface, and an opening; and
a metal liner layer disposed over at least the sidewalls, and the bottom surface;
removing at least a portion of the metal liner layer;
partially filing the recessed feature with a molybdenum metal by a cyclical deposition-etch process, wherein a unit cycle of the cyclical deposition-etch process comprises:
partially filing the recessed feature with molybdenum metal by performing one or more unit cycles of a first cyclical deposition process, wherein the first cyclical deposition process deposits a molybdenum metal at a greater deposition rate per cycle proximate to the bottom surface of the recessed feature compared with the deposition rate per cycle proximate to the opening of the recessed feature; and
partially etching the molybdenum metal; and
filing the recessed feature with additional molybdenum metal by performing one or more unit cycles of a second cyclical deposition process.

2. The method of claim 1, wherein a unit cycle of the first cyclical deposition process and a unit cycle of the second cyclical deposition process comprises, contacting the substrate with a first vapor phase reactant comprising a molybdenum oxyhalide, and contacting the substrate with a second vapor phase reactant comprising a reducing agent.

3. The method of claim 2, wherein the molybdenum oxyhalide comprises molybdenum (IV) dichloride dioxide (MoO₂Cl₂).

4. The method of claim 1, wherein removing at least a portion of the metal liner layer further comprises, contacting the metal liner layer with a gaseous chloride based etchant.

5. The method of claim 4, wherein contacting the metal liner layer with the gaseous chloride based etchant further comprises, removing a greater portion of the metal liner layer proximate to the opening of the recessed feature compared with the portion of the metal liner layer removed proximate to the bottom of the recessed feature.

6. The method of claim 4, wherein the gaseous chloride based etchant comprises at least of one molybdenum pentachloride (MoCl₅), and tungsten pentachloride (WCl₅).

7. The method of claim 1, wherein the metal liner layer comprises a metal nitride liner layer.

8. The method of claim 1, wherein partially filing the recessed feature with a molybdenum metal by a cyclical deposition-etch process further comprises, forming a greater thickness of the molybdenum metal proximate to the bottom surface of the recessed feature compared with the thickness of the molybdenum metal formed proximate to the opening of the recessed feature.

9. The method of claim 8, wherein partially filing and subsequently filing the recessed feature with molybdenum metal and additional molybdenum metal further comprises, seamlessly filling the recessed feature.

10. The method of claim 1, wherein partially etching the molybdenum metal comprises a cyclical etch-purge process.

11. A structure formed according to the method of claim 1.

12. A method for seamlessly filling a recessed feature on a substrate with a molybdenum metal, the method comprising:
providing a substrate including a recessed feature; the recessed feature comprising an opening as well as sidewalls and a bottom surface covered with a metal nitride liner;
preferentially etching the metal nitride liner proximate to the opening of the recessed feature, wherein the etch rate of the metal nitride liner proximate to the opening of the recessed feature is up to 300% greater than the etch rate of the metal nitride liner proximate to the bottom surface of the recessed feature;
partially filing the recessed feature with a molybdenum metal by a cyclical deposition-etch process, wherein the cyclical deposition-etch process preferentially forms a molybdenum metal proximate to the bottom surface of the recessed feature and wherein the etch portion of the cyclical deposition-etch process; and
filing the recessed feature with additional molybdenum metal by performing one or more unit cycles of a cyclical deposition process.

13. The method of claim 12, wherein preferentially etching the metal nitride liner further comprises, contacting the metal nitride liner with a gaseous chloride based etchant.

14. The method of claim 13, wherein the chloride based etchant comprises at least one of molybdenum pentachloride (MoCl₅), and tungsten pentachloride (WCl₅).

15. The method of claim 12, wherein preferentially etching the metal nitride liner layer further comprises, etching the metal nitride liner proximate to the opening of the recessed feature at a higher etch rate compared with the etch rate of the metal nitride liner proximate to the bottom of the recessed feature.

16. The method of claim 15, wherein the metal nitride liner proximate to the opening of the recessed feature is preferentially etched to a thickness of less than 5 Angstroms.

17. The method of claim 12, wherein the metal nitride liner comprises at least one of a titanium nitride liner, and a tantalum nitride liner.

18. The method of claim 12, wherein preferentially etching the metal nitride liner comprises a cyclical etch-purge process

19. A structure formed according to the method of claim 12.

20. An apparatus configured for performing the method of claim 12.
